(19) United States
(12) Patent Application Publication
(10) Pub. No.: US 2020/0392003 A1
(43) Pub. Date: Dec. 17, 2020

(54) SYSTEMS AND TECHNIQUES FOR MODIFYING ELECTRONIC PROPERTIES OF MATTER

(71) Applicant: CONTINUUM ENERGY TECHNOLOGIES, LLC, Fall River, MA (US)

(72) Inventor: Christopher J. Nagel, Wayland, MA (US)

(21) Appl. No.: 16/657,129

(22) Filed: Oct. 18, 2019

Related U.S. Application Data
(60) Provisional application No. 62/860,544, filed on Jun. 12, 2019.
(60) Provisional application No. 62/864,866, filed on Jun. 21, 2019.
(60) Provisional application No. 62/899,333, filed on Sep. 12, 2019.

(51) Int. Cl. C01B 32/21; C23C 14/46; C23C 14/18; C23C 14/34

(52) U.S. Cl. CPC C01B 32/21; C23C 14/3435; C23C 14/185; C23C 14/46

(57) ABSTRACT

Systems and techniques are disclosed for modifying electronic properties of a sample operated upon thereby. The disclosed systems may include a gas supply system and a downstream reactor system, in accordance with some embodiments. The disclosed systems also may include an intervening gas treatment system disposed between the upstream gas supply system and the downstream reactor system, in accordance with some embodiments. In at least some embodiments, the disclosed systems may include one or more sample treatment sources configured to treat the sample with either (or both) electromagnetic radiation and particle bombardment. In some embodiments, the disclosed systems also may include one or more gas treatment sources configured to treat a given gas flow with either (or both) electromagnetic radiation and particle bombardment. In operation of the disclosed systems, one or more gas flows (optionally treated) are delivered to contact (or otherwise interact with) the sample, modifying its electronic structure.

### CROSS-REFERENCE TO RELATED APPLICATIONS

This patent application claims the benefit of: (1) U.S. Provisional Patent Application No. 62/860,544, filed on Jun. 12, 2019; (2) U.S. Provisional Patent Application No. 62/864,866, filed on Jun. 21, 2019; and (3) U.S. Provisional Patent Application No. 62/899,333, filed on Sep. 12, 2019. Each of these patent applications is herein incorporated by reference in its entirety.

### FIELD OF THE DISCLOSURE

The present disclosure relates to modifying electronic properties of matter and, more particularly, to systems and techniques for transmuting materials, manufacturing metals (or alloys thereof), and/or producing new chemical elements.

### BACKGROUND

Generally, the characteristics of matter stem from the electronic structure of the atoms which comprise it. In changing the electronic structure of matter, such as by adding or removing subatomic particles, the nature of the matter changes as well. This process, known as transmutation, can occur naturally or artificially. In either case, after modification, the resultant matter may be significantly different in composition and behavior from its predecessor.

### SUMMARY

The subject matter of this application may involve, in some cases, interrelated products, alternative solutions to a particular problem, and/or a plurality of different uses of a single system or article.

One example embodiment provides a method of manufacturing a metal or alloy thereof. The method includes delivering at least one gas to interact with a carbon sample, wherein the at least one gas is non-reactive with respect to the carbon sample. The method further includes subjecting the carbon sample to at least one of electromagnetic radiation, an electromagnetic field, and subatomic particle bombardment such that the carbon sample thereafter further includes the metal or alloy thereof without the carbon sample previously having been in contact with said metal or alloy thereof, wherein: the electromagnetic radiation is selected from the group consisting of light, laser light, an electromagnetic field, and gamma radiation; and the subatomic particle bombardment involves subatomic particles selected from the group consisting of protons, neutrons, and electrons.

In some cases, prior to carrying out the method, the carbon sample includes at least 95% graphite by weight. In some cases, the metal or alloy thereof includes a rare earth metal. In some cases, the metal or alloy thereof includes a platinum-group element. In some such instances, the metal or alloy thereof includes platinum. In some such instances, the amount of platinum present is at least one order of magnitude higher than prior to carrying out the method. In some cases, the metal or alloy thereof includes iron. In some such instances, the amount of iron present is at least one order of magnitude higher than prior to carrying out the method. In some other such instances, the amount of iron present is at least two orders of magnitude higher than prior to carrying out the method. In some cases, the metal or alloy thereof includes a transition metal.

In some cases, subjecting the carbon sample to at least one of electromagnetic radiation, an electromagnetic field, and subatomic particle bombardment occurs either: before delivering the at least one gas to interact with the carbon sample; during delivering the at least one gas to interact with the carbon sample; or after delivering the at least one gas to interact with the carbon sample. In some other cases, subjecting the carbon sample to at least one of electromagnetic radiation, an electromagnetic field, and subatomic particle bombardment occurs at least two of: before delivering the at least one gas to interact with the carbon sample; during delivering the at least one gas to interact with the carbon sample; and after delivering the at least one gas to interact with the carbon sample. In some still other cases, subjecting the carbon sample to at least one of electromagnetic radiation, an electromagnetic field, and subatomic particle bombardment occurs each of: before delivering the at least one gas to interact with the carbon sample; during delivering the at least one gas to interact with the carbon sample; and after delivering the at least one gas to interact with the carbon sample.

In some cases, the method further includes subjecting the carbon sample to induction heating. In some such instances, subjecting the carbon sample to the induction heating occurs either: before delivering the at least one gas to interact with the carbon sample; during delivering the at least one gas to interact with the carbon sample; or after delivering the at least one gas to interact with the carbon sample. In some other such instances, subjecting the carbon sample to the induction heating occurs at least two of: before delivering the at least one gas to interact with the carbon sample; during delivering the at least one gas to interact with the carbon sample; and after delivering the at least one gas to interact with the carbon sample. In some still other such instances, subjecting the carbon sample to the induction heating occurs at each of: before delivering the at least one gas to interact with the carbon sample; during delivering the at least one gas to interact with the carbon sample; and after delivering the at least one gas to interact with the carbon sample.

In some cases, prior to delivering the at least one gas to interact with the carbon sample, the method further includes subjecting the at least one gas to at least one of: at least one of electromagnetic radiation and subatomic particle bombardment; and at least one of an electromagnetic field and induction heating.

In some cases, a metal or alloy thereof manufactured via the method is provided.

Another example embodiment provides a composition including: a carbon body; and a manufactured metal or alloy thereof hosted by the carbon body, wherein the manufactured metal or alloy is of an ore-type formation pattern as hosted by the carbon body. In some cases, the carbon body includes at least 95% graphite by weight. In some cases, the metal or alloy thereof includes a rare earth metal. In some cases, the metal or alloy thereof includes a platinum-group element. In some such instances, the metal or alloy thereof includes platinum. In some cases, the metal or alloy thereof includes iron. In some cases, the metal or alloy thereof includes a transition metal.

Another example embodiment provides a system configured to manufacture a metal or alloy thereof. The system includes at least one sample containment configured to contain a carbon sample and to deliver at least one gas to interact with the carbon sample, wherein the at least one gas is non-reactive with respect to the carbon sample. The system further includes at least one sample treatment source external to the at least one sample containment and configured to subject the carbon sample to at least one of electromagnetic radiation, an electromagnetic field, and subatomic particle bombardment such that the carbon sample thereafter further includes the metal or alloy thereof without the carbon sample previously having been in contact with said metal or alloy thereof, wherein: the electromagnetic radiation is selected from the group consisting of light, laser light, an electromagnetic field, and gamma radiation; and the subatomic particle bombardment involves subatomic particles selected from the group consisting of protons, neutrons, and electrons.

In some cases, the system further includes a coil at least partially surrounding the at least one sample containment, wherein the coil is configured to be driven so as to subject the carbon sample to induction heating.

In some cases, the system further includes at least one gas containment configured to have the at least one gas flow therethrough to be delivered to interact with the carbon sample. The system further includes at least one gas treatment source external to the at least one gas containment and configured to subject the at least one gas to at least one of: at least one of electromagnetic radiation and subatomic particle bombardment, wherein the electromagnetic radiation is selected from the group consisting of light, a static magnetic field, an alternating magnetic field, a static electric field, and an alternating electric field; and at least one of an electromagnetic field and induction heating.

The features and advantages described herein are not all-inclusive and, in particular, many additional features and advantages will be apparent to one of ordinary skill in the art in view of the drawings, specification, and claims. Moreover, it should be noted that the language used in the specification has been selected principally for readability and instructional purposes and not to limit the scope of the inventive subject matter.

### BRIEF DESCRIPTION OF THE DRAWINGS

FIG. 1A is a block diagram illustrating a system configured in accordance with an embodiment of the present disclosure.

FIG. 1B is a block diagram illustrating a system configured in accordance with another embodiment of the present disclosure.

FIG. 2A is a flow diagram illustrating a method of modifying an electronic property of a sample, in accordance with an embodiment of the present disclosure.

FIG. 2B is a flow diagram illustrating a method of operating upon a sample in modifying an electronic property thereof, in accordance with an embodiment of the present disclosure.

FIG. 2C is a flow diagram illustrating a method of treating at least one gas for use in operating upon a sample in modifying an electronic property thereof, in accordance with an embodiment of the present disclosure.

FIGS. 3A and 3B schematically illustrate energy dispersive X-ray fluorescence (ED-XRF) top scan and side scan methodologies, respectively, utilized in analyzing untailored and tailored graphite rods, in accordance with an embodiment of the present disclosure.

FIGS. 4-7 graphically illustrate spectra obtained from ED-XRF of first, second, third, and fourth graphite rod samples both before and after tailoring, in accordance with an embodiment of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated in light of this disclosure, the accompanying drawings are not intended to be drawn to scale or to limit the described embodiments to the specific configurations shown.

### DETAILED DESCRIPTION

Systems and techniques are disclosed for modifying electronic properties of (e.g., tailoring) a sample operated upon thereby. The disclosed systems may include a gas supply system and a downstream reactor system, in accordance with some embodiments. The disclosed systems also may include an intervening gas treatment system disposed between the upstream gas supply system and the downstream reactor system, in accordance with some embodiments. In at least some embodiments, the disclosed systems may include one or more sample treatment sources configured to treat the sample with either (or both) electromagnetic radiation and particle bombardment. In some embodiments, the disclosed systems also may include one or more gas treatment sources configured to treat a given gas flow with either (or both) electromagnetic radiation and particle bombardment. In operation of the disclosed systems, one or more gas flows (optionally treated) are delivered to contact (or otherwise interact with) the sample, modifying its electronic structure.

General Overview

In accordance with some embodiments of the present disclosure, systems and techniques are disclosed for modifying electronic properties of (e.g., tailoring) a sample operated upon thereby. The disclosed systems may include a gas supply system and a downstream reactor system, in accordance with some embodiments. The disclosed systems also may include an intervening gas treatment system disposed between the upstream gas supply system and the downstream reactor system, in accordance with some embodiments. In at least some embodiments, the disclosed systems may include one or more sample treatment sources configured to treat the sample with either (or both) electromagnetic radiation and particle bombardment. In some embodiments, the disclosed systems also may include one or more gas treatment sources configured to treat a given gas flow with either (or both) electromagnetic radiation and particle bombardment. In operation of the disclosed systems, one or more gas flows (optionally treated) are delivered to contact (or otherwise interact with) the sample, modifying its electronic structure, in accordance with some embodiments.

The disclosed systems may be configured, in accordance with some embodiments, for use in tailoring (e.g., modifying one or more electronic properties of) a sample operated upon thereby. In accordance with some embodiments, the disclosed systems may be configured for use in transmuting materials and/or producing new chemical elements not originally present in a sample operated upon thereby and with which the sample has not come in contact (e.g., from some other source). In accordance with some embodiments, the disclosed systems may be configured to use one or more forms of electromagnetic energy (e.g., visible light of a specific wavelength range, electrical current of a known frequency of oscillations, and so on) and one or more materials (e.g., inert or non-reactive gases, carbon, or metals) for (1) the production of one or more desired properties (e.g., conductivity, hardness, or reactivity, among others) in the material and/or (2) the manufacture of particles of a given composition or nature. Numerous additional and different suitable uses and applications will be apparent in light of this disclosure.

In accordance with some embodiments, techniques disclosed herein may be utilized, for example, in manufacturing one or more metals or alloys thereof from a given sample (e.g., such as a graphite rod or other body). For instance, and as evidenced by the various data provided herein, metals such as iron (Fe) and platinum (Pt) may be manufactured using techniques described herein, in accordance with some embodiments. More generally, and in accordance with some embodiments, one or more rare earth elements—cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and yttrium (Y)—may be manufactured using techniques described herein. In accordance with some embodiments, one or more platinum group elements—ruthenium (Ru), rhodium (Rh), palladium (Pd), osmium (Os), iridium (Ir), and platinum (Pt)—may be manufactured using techniques described herein. Additionally, experimental data indicate that lesser increases in the presence of other elements beyond these examples may be provided using the disclosed techniques, in accordance with some embodiments. Thus, in a more general sense, the disclosed techniques may be utilized, in accordance with some embodiments, in manufacturing or otherwise producing metal(s) or alloy(s) thereof from different original materials.

In accordance with some embodiments, techniques disclosed herein may be utilized, for example, in making a composition of matter which is either (1) a natural or synthetic material with a unique property or (2) particle formation of a new material. An example of the former may be, for instance, magnetic copper (Cu). An example of the latter may be, for instance, extracted tantalum (Ta) from a pure iron (Fe)/manganese (Mn)/vanadium (V) alloy. In accordance with some embodiments, other results from use of techniques disclosed herein may include, for example: (1) magnetism in non-magnetic materials accompanied by unique physical attraction capabilities; (2) order of magnitude changes in physical properties, such as hardness, ductility, and color, to name a few, accompanied by changes in chemical properties, such as reactivity and conductivity, among others; (3) sustained charge in a molten metal bath (Hall effect); (4) a partial Meissner effect at room temperature (e.g., an effect previously affiliated only with superconductor materials); and/or (5) changes to signature X-ray energy emissions of excited elements.

System Architecture and Operation

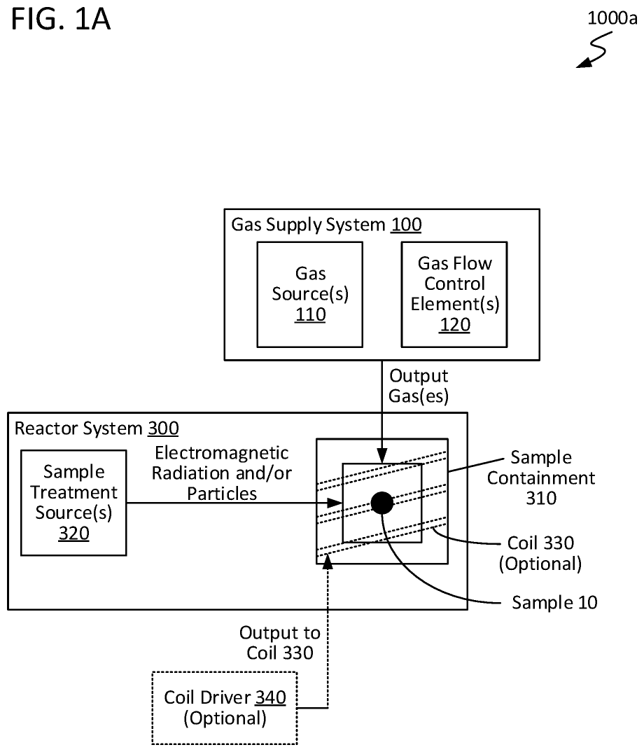

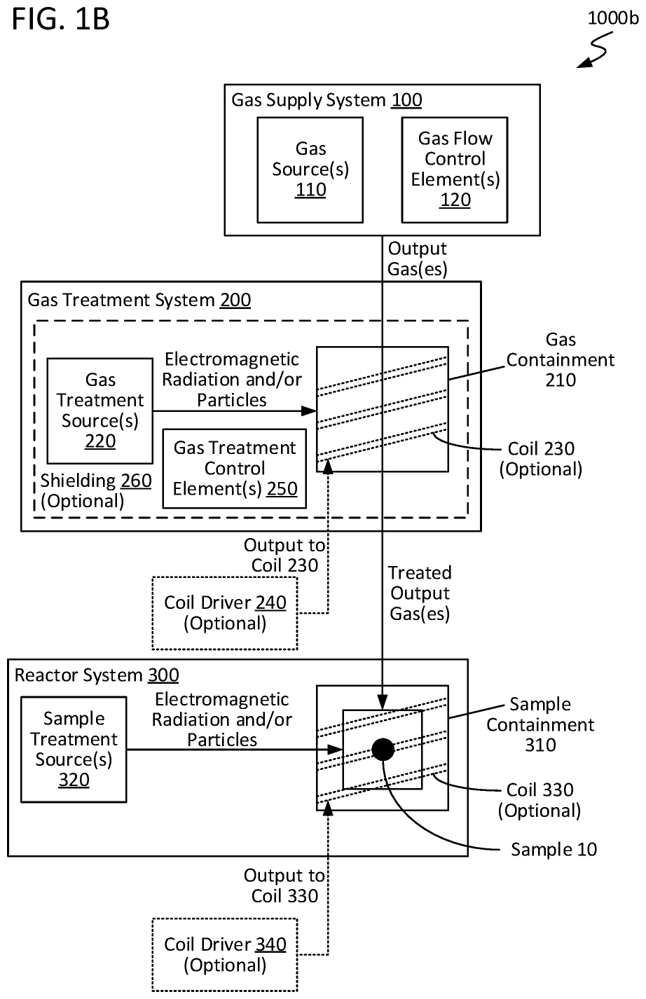

FIG. 1A is a block diagram illustrating a system 1000a configured in accordance with an embodiment of the present disclosure. FIG. 1B is a block diagram illustrating a system 1000b configured in accordance with another embodiment of the present disclosure. For consistency and ease of understanding of the present disclosure, systems 1000a and 1000b may be collectively referred to herein generally as system 1000, except where separately referenced.

As can be seen from FIGS. 1A-1B, system 1000 may include (or otherwise may involve in its operation) a gas supply system 100 and a downstream reactor system 300, in accordance with some embodiments. As can be seen from FIG. 1B, for instance, system 1000 optionally further may include (or otherwise may involve in its operation) a gas treatment system 200 intervening between upstream gas supply system 100 and downstream reactor system 300, in accordance with some embodiments. In any case, system 1000 may be configured to operate upon a sample 10 within reactor system 300. Each of these various elements of systems 1000a, 1000b is discussed in turn below. More generally, FIGS. 1A-1B illustrate the relationships of the various constituent elements of systems 1000a, 1000b and the overall flow of material and energy within systems 1000a, 1000b, in accordance with some embodiments.

As noted above, system 1000 may include a gas supply system 100. Gas supply system 100 may be configured, in accordance with some embodiments, to supply one or more controlled gas flows for either (or both) downstream gas treatment system 200 (if optionally included, as in system 1000b) and reactor system 300. In accordance with some embodiments, gas supply system 100 may be configured for mixing gases at a given desired ratio. To such ends, gas supply system 100 may include, in accordance with some embodiments, one or more gas sources 110 and one or more gas flow control elements 120, each discussed in turn below.

A given gas source 110 may be of any suitable configuration, as will be apparent in light of this disclosure. In some cases, a given gas source 110 may be, for example, a pressurized gas cylinder (or other suitable vessel) containing volume(s) of one or more gases for use in operation of system 1000. In some other cases, a given gas source 110 may involve, for example, provision of some chemical reaction between reactants so as to generate one or more gases for use in operation of system 1000. Other suitable types and configurations for a given gas source 110 will depend on a given target application or end-use and will be apparent in light of this disclosure.

A given gas flow control element 120 may be of any suitable configuration, as will be apparent in light of this disclosure. In some cases, a given gas flow control element 120 may include a programmable logic array (or other suitable electronic componentry) for use in controlling gas flow rate(s) of gas(es) from a given gas source 110 (or gas supply system 100 more generally). In some cases, a given gas flow control element 120 may be configured to provide for metering of any such gas flow(s). Other suitable types and configurations for a given gas flow control element 120 will depend on a given target application or end-use and will be apparent in light of this disclosure.

Regarding gas types, gas supply system 100 may be configured to supply any of a wide range of gases for use in operation of system 1000. For instance, some example suitable gases may include one (or any combination) of argon (Ar), xenon (Xe), neon (Ne), krypton (Kr), hydrogen (H), helium (He), nitrogen (N), carbon monoxide (CO), and carbon dioxide (CO₂). It should be noted, however, that the present disclosure is not intended to be limited only to these specific example gases, as more generally, additional and/or different suitable gases for use in operation of system 1000 will be apparent in light of this disclosure. In accordance with some embodiments, one or more inert gases (e.g., noble gases) may be utilized. In accordance with some embodiments, one or more non-reactive gases (e.g., gases which are non-reactive at least with respect to a given sample 10).

As noted above, system 1000 may include a reactor system 300. Reactor system 300 may be configured, in accordance with some embodiments, to provide a reactor environment for one or more samples 10 operated upon by system 1000. To such ends, reactor system 300 may include, in accordance with some embodiments, one or more sample containments 310 and one or more sample treatment sources 320, each discussed in turn below. In some embodiments, reactor system 300 optionally also may include a coil 330 and associated coil driver 340, discussed below. As will be appreciated in light of this disclosure, in at least some cases, reactor system 300 generally may be configured, in part or in whole, as a magnetic levitation (maglev) reactor.

A given sample containment 310 may be configured, in accordance with some embodiments, to contain a given sample 10, in part or in whole, to be operated upon by system 1000. A given sample containment 310 may be configured, in accordance with some embodiments, to permit gas(es) received (e.g., either directly or indirectly) from upstream gas supply system 100 to flow therethrough, providing such gas(es) for contact (or other desired interaction) with a given sample 10 within such sample containment 310. In some embodiments, a given sample containment 310 may be, at least in part, an optically transparent vessel. As will be appreciated in light of this disclosure, in at least some instances, provision of an optically transparent sample containment 310 may facilitate treatment of sample 10 with at least some types of the output (e.g., electromagnetic radiation, such as light) of a given sample treatment source 320. The dimensions and geometry, as well as the material composition, of a given sample containment 310 may be customized, as desired for a given target application or end-use. In an example case, a given sample containment 310 may be about 12 inches long and have a diameter of about 1 inch. In some instances, a given sample containment 310 may be generally tubular in shape, having a generally curved (e.g., circular, elliptical, or other closed-curve geometry) or generally polygonal (e.g., square, rectangular, or other multi-sided geometry) cross-sectional profile. In some instances, a given sample containment 310 may be made of an optically transparent material, such as quartz (e.g., optical quartz) or silica, to name a few. Other suitable types and configurations for a given sample containment 310 will depend on a given target application or end-use and will be apparent in light of this disclosure.

Optional coil 330 may be configured, in accordance with some embodiments, for use in subjecting a given sample 10 within a given sample containment 310 to either (or both) (1) an electromagnetic field (DC or AC), such as a magnetic field (static or dynamic), and (2) induction heating. More generally, coil 330 may be configured for use in thermal and/or electromagnetic field cycling of sample 10, in accordance with some embodiments. If optionally included, a given coil 330 may be disposed substantially proximal to a given sample containment 310. For instance, in some embodiments, a given coil 330 may be wrapped around a given sample containment 310, in part or in whole. In some other embodiments, a given coil 330 may be disposed adjacent one or more regions of a given sample containment 310, in part or in whole. The dimensions and arrangement of a given coil 330, as well as the quantity and pitch/spacing of any windings thereof, may be customized, as desired for a given target application or end-use. If reactor system 300 optionally includes a coil 330, such coil 330 may be operatively connected with a coil driver 340. Coil driver 340 may be configured, in accordance with some embodiments, as a power source, voltage generator, or other signal generator for driving an associated coil 330. In some cases, coil driver 340 may be an induction heating system, such as, for example, an EASYHEAT induction heating system commercially available from Ambrell Corp. As will be appreciated in light of this disclosure, coil driver 340 may be either a component of or discrete and separate from reactor system 300, as desired. Other suitable types and configurations for optional coil 330 and coil driver 340 will depend on a given target application or end-use and will be apparent in light of this disclosure.

A given sample treatment source 320 may be configured, in accordance with some embodiments, to provide output for contact (or other desired interaction) with a given sample 10 within a given sample containment 310. A given sample treatment source 320 may be configured, in accordance with some embodiments, to deliver either (or both) (1) electromagnetic radiation and (2) one or more particles (e.g., particle bombardment) to a given sample 10. Some examples of suitable electromagnetic radiation output may include light (e.g., laser light), gamma radiation, electromagnetic fields (AC and/or DC), and electrical currents (AC and/or DC), to name a few. Some examples of suitable particle output may include subatomic particles, such as any one (or combination) of protons, electrons, and neutrons, to name a few. Additional and/or different types of particles may be utilized, as desired for a given target application or end-use, in accordance with some embodiments. In accordance with some embodiments, one or more sample treatment sources 320 may be configured to provide a combination of electromagnetic radiation and particle output. In accordance with some embodiments, one or more characteristics of the output of a given sample treatment source 320 may be manipulated, such as, for example, angle of incidence (e.g., angle of irradiation and/or particle bombardment), sequencing (e.g., order and duration of irradiation and/or particle bombardment), and energy (e.g., wavelength and/or frequency of irradiation and/or particle bombardment), among other variables. Other suitable types and configurations for a given sample treatment source 320 will depend on a given target application or end-use and will be apparent in light of this disclosure.

As noted above, system 1000 (e.g., system 1000b) optionally may include a gas treatment system 200. Gas treatment system 200 may be configured, in accordance with some embodiments, to provide treatment of gas(es) received (e.g., either directly or indirectly) from upstream gas supply system 100 before delivery of such treated gas(es) to downstream reactor system 300. To such ends, gas treatment system 200 may include, in accordance with some embodiments, one or more gas containments 210, one or more gas treatment sources 220, and one or more gas treatment control elements 250, each discussed in turn below. In some embodiments, gas treatment system 200 optionally also may include a coil 230 and associated coil driver 240, discussed below. In some embodiments, gas treatment system 200 optionally also may include shielding 260, discussed below. As will be appreciated in light of this disclosure, in at least some cases, gas treatment system 200 generally may be configured as a light box for treating (e.g., activating, triggering, or otherwise conditioning) gas(es) upstream of reactor system 300. As will be further appreciated in light of this disclosure, the dimensions and form factor of gas treatment system 200 may be customized, as desired for a given target application or end-use. In an example case, gas treatment system 200 may be a light box that is about 24 inches in length, about 12 inches in width, and about 12 inches in height.

A given gas containment 210 may be configured, in accordance with some embodiments, to contain, at least temporarily, a given gas received from upstream gas supply system 100 to be delivered to downstream reactor system 300 in operating upon sample 10 with system 1000. A given gas containment 210 may be configured, in accordance with some embodiments, to permit gas(es) received (e.g., either directly or indirectly) from upstream gas supply system 100 to flow therethrough. A given gas containment 210 may be configured, in accordance with some embodiments, to carry the gas(es) past a given gas treatment source 220 (discussed below) such that the gas(es) receive (or are otherwise exposed to) the output of such gas treatment source 220. In some embodiments, a given gas containment 210 may be, at least in part, an optically transparent vessel. As will be appreciated in light of this disclosure, in at least some instances, provision of an optically transparent gas containment 210 may facilitate treatment of the gas(es) flowing therethrough with at least some types of the output (e.g., electromagnetic radiation, such as light) of a given gas treatment source 220. The dimensions and geometry, as well as the material composition, of a given gas containment 210 may be customized, as desired for a given target application or end-use. As will be appreciated in light of this disclosure, a given gas containment 210 may be of any of the various configurations and material compositions noted above, for instance, with respect to sample containment 310, in accordance with some embodiments. In an example case, a given gas containment 210 may be made of a glass. Other suitable types and configurations for a given gas containment 210 will depend on a given target application or end-use and will be apparent in light of this disclosure.

Optional coil 230 may be configured, in accordance with some embodiments, for use in subjecting the one or more gases flowing through a given gas containment 210 to either (or both) (1) an electromagnetic field (DC or AC) and (2) induction heating. More generally, coil 230 may be configured for use in thermal and/or electromagnetic field cycling of the gas(es), in accordance with some embodiments. If optionally included, a given coil 230 may be disposed substantially proximal to a given gas containment 210. For instance, in some embodiments, a given coil 230 may be wrapped around a given gas containment 210, in part or in whole. In some other embodiments, a given coil 230 may be disposed adjacent one or more regions of a given gas containment 210, in part or in whole. The dimensions and arrangement of a given coil 230, as well as the quantity and pitch/spacing of any windings thereof, may be customized, as desired for a given target application or end-use. If gas treatment system 200 optionally includes a coil 230, such coil 230 may be operatively connected with a coil driver 240. As will be appreciated in light of this disclosure, coil driver 240 may be of any of the various configurations noted above, for instance, with respect to coil driver 340, in accordance with some embodiments. As will be further appreciated in light of this disclosure, coil driver 240 may be either a component of or discrete and separate from gas treatment system 200, as desired. Other suitable types and configurations for optional coil 230 and coil driver 240 will depend on a given target application or end-use and will be apparent in light of this disclosure.

A given gas treatment source 220 may be configured, in accordance with some embodiments, to provide output for contact (or other desired interaction) with the one or more gases flowing through a given gas containment 210. A given gas treatment source 220 may be configured, in accordance with some embodiments, to deliver either (or both) (1) electromagnetic radiation and (2) one or more particles (e.g., particle bombardment) to the one or more gases flowing through a given gas containment 210. As will be appreciated in light of this disclosure, a given gas treatment source 220 may be configured to output any of the various types of output discussed above, for instance, with respect to sample treatment source 320, in accordance with some embodiments. In some cases, a given gas treatment source 220 may be, for example, a light source configured to emit light of a given desired spectrum. For example, in some instances, any one (or combination) of visible, ultraviolet, and infrared may be emitted. In some cases, a given gas treatment source 220 may be, for example, a magnetic field source configured to emit a magnetic field of static or alternating nature (e.g., alternating in time, frequency, amplitude, etc.). In some cases, a given gas treatment source 220 may be, for example, an electric field source configured to emit an electric field of static or alternating nature (e.g., alternating in time, frequency, amplitude, etc.). In some instances, a given gas treatment source 220 may be (or otherwise may involve), for example, one or more filters or other modifiers configured to adjust the output delivered to the one or more gases flowing through a given gas containment 210. In accordance with some embodiments, a single or multiple gas treatment sources 220 may be configured to provide a combination of electromagnetic radiation and particle output. In accordance with some embodiments, one or more characteristics of the output of a given gas treatment source 220 may be manipulated, such as, for example, angle of incidence (e.g., angle of irradiation and/or particle bombardment), sequencing (e.g., order and duration of irradiation and/or particle bombardment), and energy (e.g., wavelength and/or frequency of irradiation and/or particle bombardment), among other variables. Other suitable types and configurations for a given gas treatment source 220 will depend on a given target application or end-use and will be apparent in light of this disclosure.

A given gas treatment control element 250 may be configured, in accordance with some embodiments, to adjust one or more characteristics of the output of a given gas treatment source 220. In some cases, a given gas treatment control element 250 may include a programmable logic array (or other suitable electronic componentry) for use in adjusting the output of a given gas treatment source 220 (or gas treatment system 200 more generally). In some cases, a given gas treatment control element 250 may be configured to change the positioning of a given gas treatment source 220. In some cases, a given gas treatment control element 250 may be configured to change the current and/or frequency driving a given gas treatment source 220. In some cases, a given gas treatment control element 250 may be configured to turn on/off a given gas treatment source 220 or otherwise change the power state (e.g., low power below a given threshold, high power above a given threshold, full power, etc.) thereof. In some cases, a given gas treatment control element 250 may be configured to provide for continuous, periodic, or intermittent output by a given gas treatment source 220. In an example case, a given gas treatment control element 250 may be (or otherwise may involve) a rotating filter configured for chopping the output (e.g., light output) of a given gas treatment source 220. Other suitable types and configurations for a given gas treatment control element 250 will depend on a given target application or end-use and will be apparent in light of this disclosure.

Optional shielding 260 may be configured, in accordance with some embodiments, to eliminate or otherwise reduce external electrostatic and/or electromagnetic influences on operation of gas treatment system 200. In some embodiments, shielding 260 may be, for example, a Faraday cage. The dimensions, shape, and material construction of optional shielding 260 may be customized, as desired for a given target application or end-use. In some cases, shielding 260 may be made from an electrically conductive material, such as aluminum (Al). Other suitable types and configurations for optional shielding 260 will depend on a given target application or end-use and will be apparent in light of this disclosure.

Regarding a given sample 10 to be operated upon by system 1000, the material composition thereof may be selected as desired for a given target application or end-use. In accordance with some embodiments, a given sample 10 may be, for example, a carbon (C) or primarily carbon-based body. In some cases, sample 10 may be comprised of graphite. In some such instances, sample 10 may comprise at least 95% graphite by weight (e.g., 95% or greater, 98% or greater, 99% or greater, 99.5% or greater, 99.9% or greater, or any other sub-range in the range of 95% or greater). The particular form factor of a given sample 10 may be customized, as desired, and in some cases may be generally that of a rod. In accordance with some other embodiments, a given sample 10 may be, for example, a metal, such as platinum (Pt), tungsten (W), nickel (Ni), iron (Fe), cobalt (Co), aluminum (Al), or tin (Sn), or an alloy of any thereof. In accordance with some other embodiments, a given sample 10 may be, for example, a metalloid, such as silicon (Si). In accordance with some embodiments, sample 10 may be a naturally occurring material, whereas in accordance with some other embodiments, sample 10 may be a synthetic material. The present disclosure, however, is not intended to be so limited, as in a more general sense, and in accordance with some embodiments, sample 10 may be any material desired to be operated upon by system 1000. The dimensions, shape, and amount of a given sample 10 also may be customized, as desired for a given target application or end-use. Other suitable types and configurations of materials for use as a given sample 10 will depend on a given target application or end-use and will be apparent in light of this disclosure.

In accordance with some embodiments, when a given sample 10 is operated upon by system 1000, one or more electronic characteristics of that sample 10 may be altered. Additionally, or alternatively, when a given sample 10 is operated upon by system 1000, particles of one or more different materials may be generated, in accordance with some embodiments. In some cases, one or more metals (and/or alloys thereof) may be made (e.g., manufactured) in the process of operating upon a given sample 10 with the disclosed techniques. For example, in some instances, a platinum-group metal, such as ruthenium (Ru), rhodium (Rh), palladium (Pd), osmium (Os), iridium (Ir), and/or platinum (Pt), may be produced. In some instances, a metal such as iron (Fe) and/or tungsten (W) may be produced. In some cases, one or more rare earth elements, such as cerium (Ce), dysprosium (Dy), erbium (Er), europium (Eu), gadolinium (Gd), holmium (Ho), lanthanum (La), lutetium (Lu), neodymium (Nd), praseodymium (Pr), promethium (Pm), samarium (Sm), scandium (Sc), terbium (Tb), thulium (Tm), ytterbium (Yb), and/or yttrium (Y), may be produced. In some cases, one or more transition metals (e.g., scandium (Sc) to zinc (Zn), yttrium (Y) to cadmium (Cd), lanthanum (La) to mercury (Hg), and/or actinides) may be produced. As will be appreciated in light of this disclosure, any of a wide range of metals and/or alloys thereof may be made using techniques disclosed herein, in accordance with some embodiments.

Methodologies

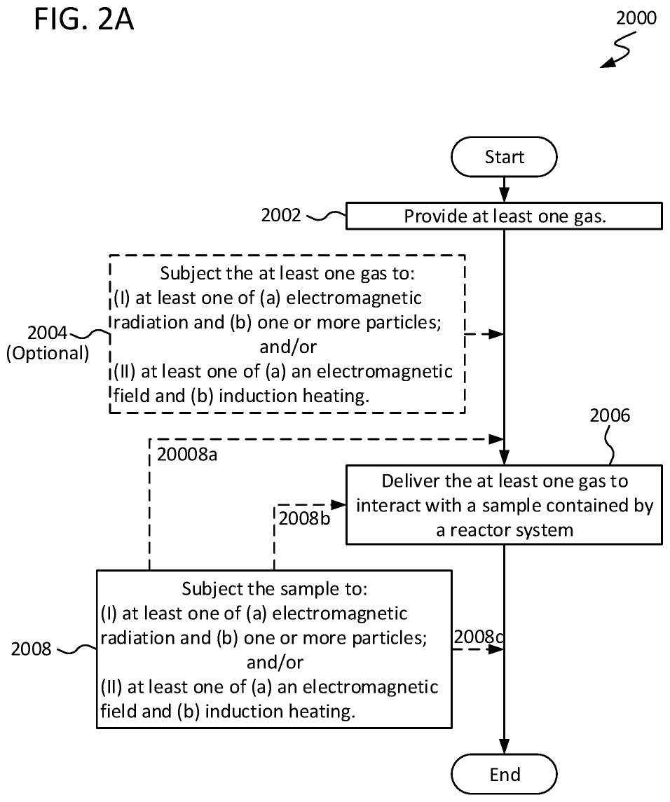

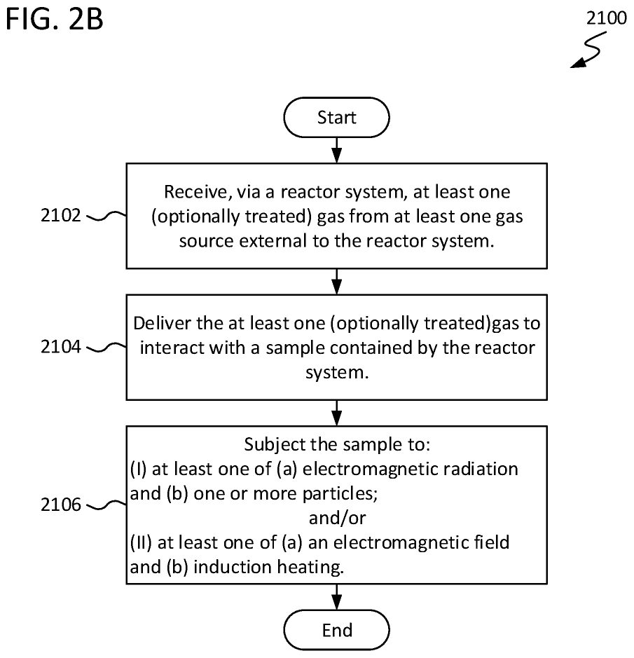

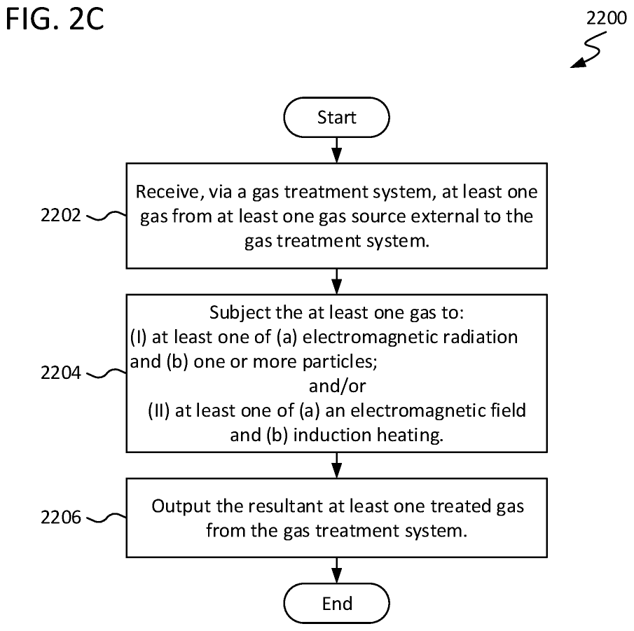

FIG. 2A is a flow diagram illustrating a method 2000 of modifying an electronic property of a sample in accordance with an embodiment of the present disclosure. As will be appreciated in light of this disclosure, one or more of the various acts of method 2000 may be performed, in part or in whole, via one or more elements of system 1000a or 1000b, in accordance with some embodiments.

As can be seen, method 2000 may begin as in block 2002 with providing at least one gas. In accordance with some embodiments, the at least one gas may be provided, for example, by one or more gas sources 110 or, more generally, a gas supply system 100 (as discussed herein). As will be appreciated in light of this disclosure, the at least one gas may be any one or combination of the various gases discussed herein, in accordance with some embodiments.

Method 2000 optionally may continue as in block 2004 with subjecting the at least one gas to: (I) at least one of (a) electromagnetic radiation and (b) one or more particles; and/or (II) at least one of (a) an electromagnetic field and (b) induction heating. In accordance with some embodiments, the electromagnetic radiation and/or one or more particles may be provided by, for example, one or more gas treatment sources 220 (as discussed herein). In accordance with some embodiments, the electromagnetic field and/or induction heating may be provided, for example, by a coil 230 (as discussed herein) at least partially surrounding (or otherwise disposed proximal to) a flow of the at least one gas.

Method 2000 may continue as in block 2006 with delivering the at least one gas (whether treated or untreated) to interact with a sample contained by a reactor system. In accordance with some embodiments, the reactor system may be, for example, a reactor system 300 (as discussed herein). As will be appreciated in light of this disclosure, the sample may be any one or combination of the various sample 10 materials discussed herein, in accordance with some embodiments. In an example case, sample 10 may be, for instance, a carbon (C) sample, such as a graphite rod or other graphite body.

Method 2000 further may include, as in block 2008, subjecting the sample to: (I) at least one of (a) electromagnetic radiation and (b) one or more particles; and/or (II) at least one of (a) an electromagnetic field and (b) induction heating. In accordance with some embodiments, subjecting the sample in this manner may occur before (2008a), during (2008b), and/or after (2008c) delivering the at least one gas to interact with the sample (block 2006). In accordance with some embodiments, the electromagnetic radiation and/or one or more particles may be provided by, for example, one or more sample treatment sources 320 (as discussed herein). In accordance with some embodiments, the electromagnetic field and/or induction heating may be provided, for example, by a coil 330 (as discussed herein) at least partially surrounding the sample.

FIG. 2B is a flow diagram illustrating a method 2100 of operating upon a sample in modifying an electronic property thereof in accordance with an embodiment of the present disclosure. As will be appreciated in light of this disclosure, one or more of the various acts of method 2100 may be performed, in part or in whole, via one or more elements of reactor system 300, in accordance with some embodiments.

As can be seen, method 2100 may begin as in block 2102 with receiving, via a reactor system, at least one gas from at least one gas source external to the reactor system. In accordance with some embodiments, the reactor system may be, for example, a reactor system 300 (as discussed herein). In accordance with some embodiments, the at least one gas source may be, for example, a gas source 110 or, more generally, a gas supply system 100 (as discussed herein). As will be appreciated in light of this disclosure, the at least one gas may be any one or combination of the various gases discussed herein, in accordance with some embodiments. As will be further appreciated, in at least some cases, the at least one gas may have been treated prior to receipt by the reactor system. In accordance with some embodiments, such treatment may be provided, for example, by a gas treatment system 200 disposed upstream of the reactor system. As will be yet further appreciated, in at least some other cases, the at least one gas may not have been so treated prior to receipt by the reactor system.

Method 2100 may continue as in block 2104 with delivering, via the reactor system, the at least one gas to interact with a sample contained by the reactor system. As will be appreciated in light of this disclosure, the sample may be any one or combination of the various sample 10 materials discussed herein, in accordance with some embodiments.

Method 2100 may continue as in block 2106 with subjecting, via the reactor system, the sample to: (I) at least one of (a) electromagnetic radiation and (b) one or more particles; and/or (II) at least one of (a) an electromagnetic field and (b) induction heating. In accordance with some embodiments, the electromagnetic radiation and/or one or more particles may be provided by, for example, one or more sample treatment sources 320 (as discussed herein). In accordance with some embodiments, the electromagnetic field and/or induction heating may be provided by, for example, a coil 330 (as discussed herein) at least partially surrounding the sample.

FIG. 2C is a flow diagram illustrating a method 2200 of treating at least one gas for use in operating upon a sample in modifying an electronic property thereof in accordance with an embodiment of the present disclosure. As will be appreciated in light of this disclosure, one or more of the various acts of method 2200 may be performed, in part or in whole, via one or more elements of gas treatment system 200, in accordance with some embodiments.

As can be seen, method 2200 may begin as in block 2202 with receiving, via a gas treatment system, at least one gas from at least one gas source external to the gas treatment system. In accordance with some embodiments, the gas treatment system may be, for example, a gas treatment system 200 (as discussed herein). In accordance with some embodiments, the at least one gas source may be, for example, a gas source 110 or, more generally, a gas supply system 100 (as discussed herein). As will be appreciated in light of this disclosure, the at least one gas may be any one or combination of the various gases discussed herein, in accordance with some embodiments.

Method 2200 may continue as in block 2204 with subjecting, via the gas treatment system, the at least one gas to: (I) at least one of (a) electromagnetic radiation and (b) one or more particles; and/or (II) at least one of (a) an electromagnetic field and (b) induction heating. In accordance with some embodiments, the electromagnetic radiation and/or one or more particles may be provided by, for example, one or more gas treatment sources 220 (as discussed herein). In accordance with some embodiments, the electromagnetic field and/or induction heating may be provided, for example, by a coil 230 (as discussed herein) at least partially surrounding (or otherwise disposed proximal to) a flow of the at least one gas.

Method 2200 may continue as in block 2206 with outputting the resultant at least one treated gas from the gas treatment system. In accordance with some embodiments, the at least one treated gas may be provided, for example, to a downstream reactor system, such as a reactor system 300 (as discussed herein).

Experimental Results

As discussed herein, the disclosed techniques may be utilized, in accordance with some embodiments, in modifying electronic properties of a given sample operated upon. Discussed below are experimental results observed from various samples which have undergone application of techniques disclosed herein, in accordance with some embodiments.

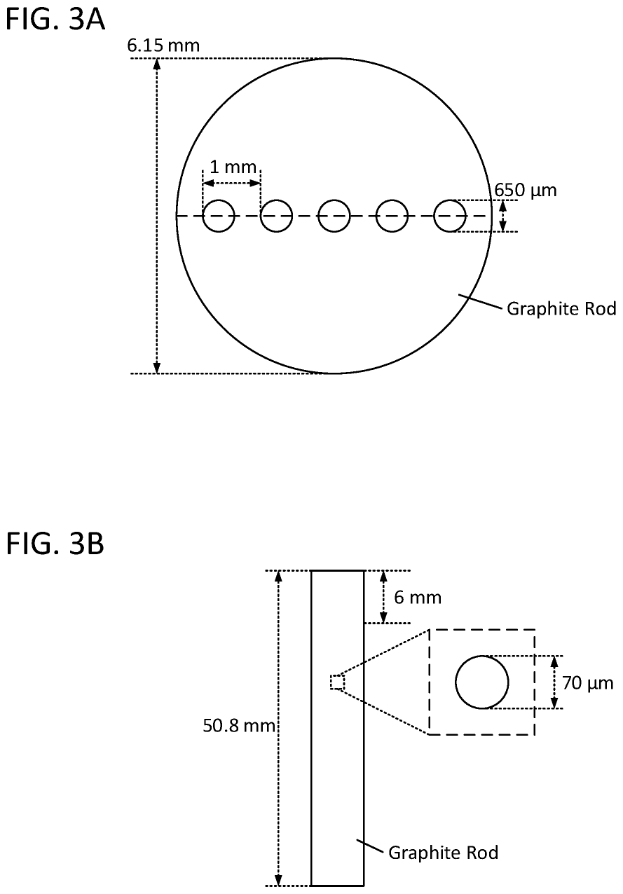

Prior to and immediately following tailoring (e.g., modifying one or more electronic properties) of a given carbon (C) graphite rod sample utilizing techniques described herein, five energy dispersive X-ray fluorescence (ED-XRF) samples were taken across a cross-section of the rod and five ED-XRF samples were taken down a length of the rod. All top and side scans were performed using a Bruker Corp. ARTAX portable micro-XRF spectrometer. Top scan samples were taken along a 4-mm line across the center of the cross-section, spaced 1 mm apart, within a rhodium (Rh) tube, each sample having a spot size diameter of 650 μm. Side scan samples were spaced 6 mm apart, within a molybdenum (Mo) tube, each sample having a spot size diameter of 70 μm. FIGS. 3A and 3B schematically illustrate the ED-XRF top scan and side scan methodologies, respectively, utilized in analyzing untailored and tailored graphite rods in accordance with some embodiments of the present disclosure. The ED-XRF analyses were performed using the following parameters: 40 kV; 1,000 μA; 315 Al filter; 240 s.

As the tested samples were graphite rods comprising at least 95% graphite by weight, glow discharge mass spectrometry (GD-MS) also was employed for direct analysis of trace elements in such high-purity conductive material. Data for Examples #1-#35 below were collected utilizing a Thermo Fisher Scientific VG9000 GD-MS soft-cell mount with no cryogenic cooling. Slow sputtering was employed to minimize clustering.

### Example #1: Untailored Sample F-002 (Control)

Table 1 below includes GD-MS data obtained for an untailored graphite rod sample ‘F-002’ used as a control in accordance with the above-described GD-MS testing methodology.

TABLE 1

| Sample # | Isotope | Test #1 | Test #2 | Test #3 | Test #4 | Avg. |
|---|---|---|---|---|---|---|
| F-002 | ⁵⁶Fe | 1.8 | 4 | 4.7 | 6.1 | 4.15 |
| F-002 | ¹⁹⁴Pt | <0.36 | <1.4 | <1.7 | <1.9 | 1.34 |
| F-002 | ¹⁹⁵Pt | 0.17 | 0.63 | 0.4 | 0.54 | 0.435 |

### Example #2: Tailored Sample F-003

Table 2 below includes GD-MS data obtained for a tailored graphite rod sample ‘F-003’ in accordance with the above-described GD-MS testing methodology.

TABLE 2

| Sample # | Isotope | Test #1 | Test #2 | Test #3 | Test #4 | Avg. |
|---|---|---|---|---|---|---|
| F-003 | ⁵⁶Fe | 220 | 440 | 280 | 210 | 287.5 |
| F-003 | ¹⁹⁴Pt | <0.68 | <1.7 | <1.9 | <2 | 1.57 |
| F-003 | ¹⁹⁵Pt | 0.41 | 0.92 | <0.72 | <0.78 | 0.7075 |

### Example #3: Tailored Sample F-004

Table 3 below includes GD-MS data obtained for a tailored graphite rod sample ‘F-004’ in accordance with the above-described GD-MS testing methodology.

TABLE 3

| Sample # | Isotope | Test #1 | Test #2 | Test #3 | Test #4 | Avg. |
|---|---|---|---|---|---|---|
| F-004 | ⁵⁶Fe | 340 | 530 | 470 | 400 | 435 |
| F-004 | ¹⁹⁴Pt | <0.54 | <1.8 | <2 | <2 | 1.585 |
| F-004 | ¹⁹⁵Pt | <0.1 | <0.35 | <0.38 | <0.38 | 0.3025 |

### Example #4: Tailored Sample F-005

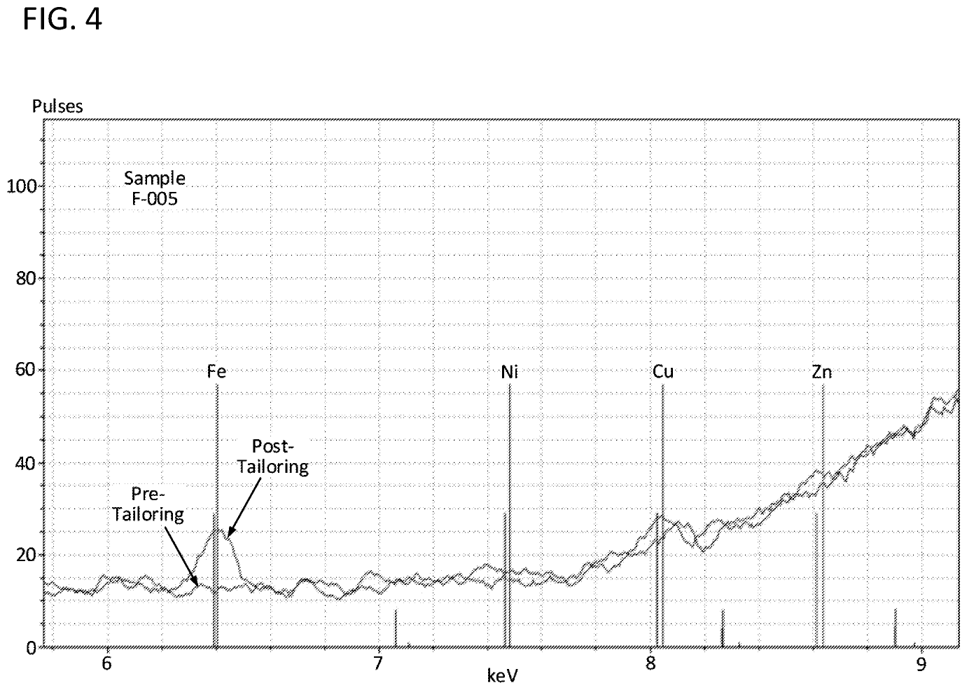

FIG. 4 graphically illustrates spectra obtained from ED-XRF of a graphite rod sample (sample label ‘F-005’) both before and after tailoring in accordance with an embodiment of the present disclosure.

Table 4 below includes GD-MS data obtained for a tailored graphite rod sample ‘F-005’ in accordance with the above-described GD-MS testing methodology.

TABLE 4

| Sample # | Isotope | Test #1 | Test #2 | Test #3 | Test #4 | Avg. |
|---|---|---|---|---|---|---|
| F-005 | ⁵⁶Fe | 300 | 270 | 230 | 210 | 252.5 |
| F-005 | ¹⁹⁴Pt | <0.32 | <0.82 | <1.1 | <1.2 | 0.86 |
| F-005 | ¹⁹⁵Pt | 0.19 | 0.59 | 1.1 | 0.6 | 0.62 |

### Example #5: Tailored Sample F-006

Table 5 below includes GD-MS data obtained for a tailored graphite rod sample ‘F-005’ in accordance with the above-described GD-MS testing methodology.

TABLE 5

| Sample # | Isotope | Test #1 | Test #2 | Test #3 | Test #4 | Avg. |
|---|---|---|---|---|---|---|
| F-006 | ⁵⁶Fe | 180 | 300 | 270 | 240 | 247.5 |
| F-006 | ¹⁹⁴Pt | <0.15 | <0.86 | <1.1 | <1.2 | 0.8275 |
| F-006 | ¹⁹⁵Pt | <0.047 | <0.27 | <0.34 | <0.36 | 0.25425 |

### Example #6: Tailored Sample F-008

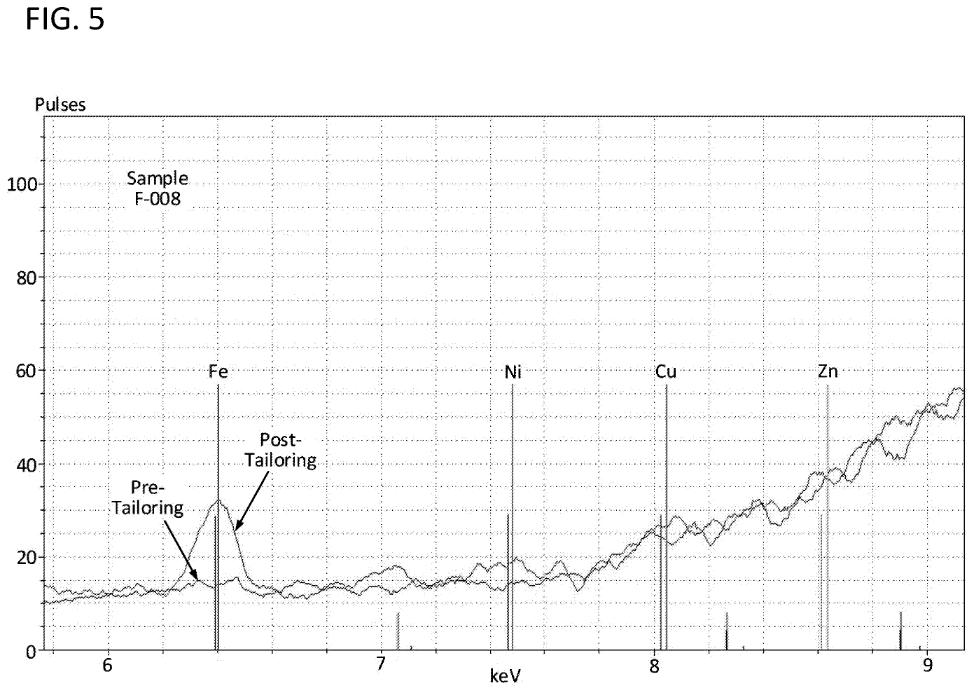

FIG. 5 graphically illustrates spectra obtained from ED-XRF of a graphite rod sample (sample label ‘F-008’) both before and after tailoring in accordance with an embodiment of the present disclosure.

Table 6 below includes GD-MS data obtained for a tailored graphite rod sample ‘F-008’ in accordance with the above-described GD-MS testing methodology.

TABLE 6

| Sample # | Isotope | Test #1 | Test #2 | Test #3 | Test #4 | Avg. |
|---|---|---|---|---|---|---|
| F-008 | ⁵⁶Fe | 910 | 680 | 500 | 390 | 620 |
| F-008 | ¹⁹⁴Pt | <0.37 | <0.91 | <1.1 | <1.2 | 0.895 |
| F-008 | ¹⁹⁵Pt | 0.48 | 0.84 | 1 | 0.74 | 0.765 |

### Example #7: Tailored Sample F-016

Table 7 below includes GD-MS data obtained for a tailored graphite rod sample ‘F-016’ in accordance with the above-described GD-MS testing methodology.

TABLE 7

| Sample # | Isotope | Test #1 | Test #2 | Test #3 | Test #4 | Avg. |
|---|---|---|---|---|---|---|
| F-016 | ⁵⁶Fe | 490 | 670 | 580 | 560 | 575 |
| F-016 | ¹⁹⁴Pt | <0.66 | <1.9 | <2 | <2.2 | 1.69 |
| F-016 | ¹⁹⁵Pt | 0.45 | 1.5 | 1.6 | 1.1 | 1.1625 |

### Example #8: Tailored Sample F-026

Table 8 below includes GD-MS data obtained for a tailored graphite rod sample ‘F-026’ in accordance with the above-described GD-MS testing methodology.

TABLE 8

| Sample # | Isotope | Test #1 | Test #2 | Test #3 | Test #4 | Avg. |
|---|---|---|---|---|---|---|
| F-026 | ⁵⁶Fe | 640 | 660 | 560 | 490 | 587.5 |
| F-026 | ¹⁹⁴Pt | <0.43 | <1.1 | <1.3 | <1.3 | 1.0325 |
| F-026 | ¹⁹⁵Pt | <0.084 | <0.21 | <0.25 | <0.26 | 0.201 |

### Example #9: Tailored Sample F-027

Table 9 below includes GD-MS data obtained for a tailored graphite rod sample ‘F-027’ in accordance with the above-described GD-MS testing methodology.

TABLE 9

| Sample # | Isotope | Test #1 | Test #2 | Test #3 | Test #4 | Avg. |
|---|---|---|---|---|---|---|
| F-027 | ⁵⁶Fe | 350 | 530 | 510 | 460 | 462.5 |
| F-027 | ¹⁹⁴Pt | <0.23 | <0.85 | <1.1 | <1.2 | 0.845 |
| F-027 | ¹⁹⁵Pt | 0.8 | 0.49 | 0.79 | 0.98 | 0.765 |

### Example #10: Tailored Sample F-028

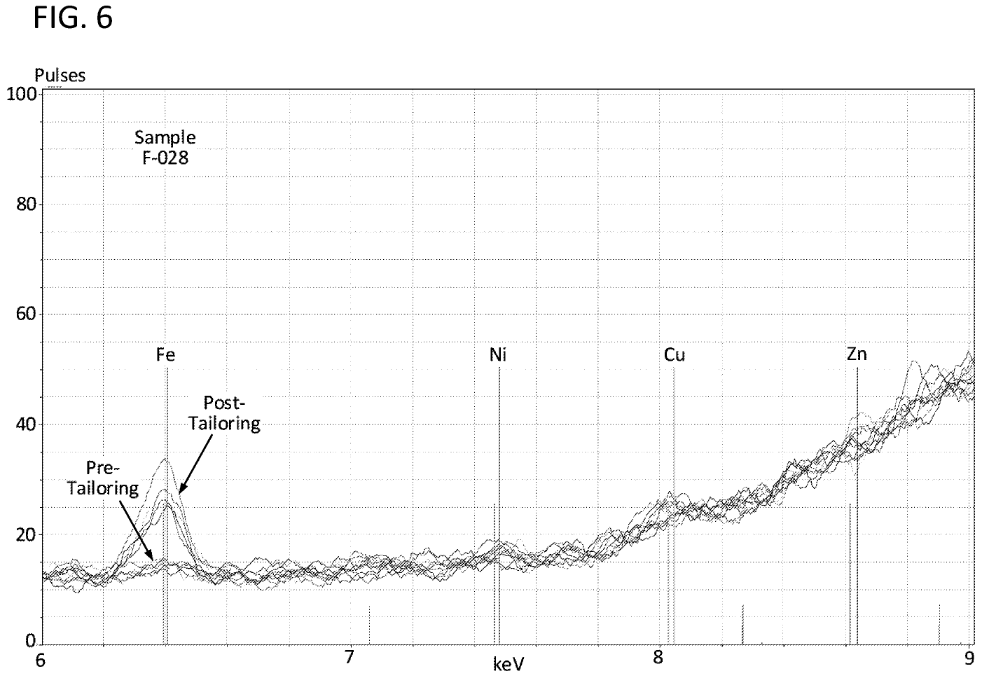

FIG. 6 graphically illustrates spectra obtained from ED-XRF of a graphite rod sample (sample label ‘F-028’) both before and after tailoring in accordance with an embodiment of the present disclosure.

Table 10 below includes GD-MS data obtained for a tailored graphite rod sample ‘F-028’ in accordance with the above-described GD-MS testing methodology.

TABLE 10

| Sample # | Isotope | Test #1 | Test #2 | Test #3 | Test #4 | Avg. |
|---|---|---|---|---|---|---|
| F-028 | ⁵⁶Fe | 510 | 590 | 540 | 490 | 532.5 |
| F-028 | ¹⁹⁴Pt | <0.43 | <1.1 | <1.3 | <1.4 | 1.0575 |
| F-028 | ¹⁹⁵Pt | 0.47 | 1 | 1.2 | 0.61 | 0.82 |

### Example #11: Tailored Sample F-029

Table 11 below includes GD-MS data obtained for a tailored graphite rod sample ‘F-029’ in accordance with the above-described GD-MS testing methodology.

TABLE 11

| Sample # | Isotope | Test #1 | Test #2 | Test #3 | Test #4 | Avg. |
|---|---|---|---|---|---|---|
| F-029 | ⁵⁶Fe | 370 | 490 | 420 | 350 | 407.5 |
| F-029 | ¹⁹⁴Pt | <0.35 | <0.92 | <1.1 | <1.1 | 0.8675 |
| F-029 | ¹⁹⁵Pt | 0.36 | 0.58 | <0.21 | <0.22 | 0.3425 |

### Example #12: Tailored Sample F-064

Table 12 below includes GD-MS data obtained for a tailored graphite rod sample ‘F-064’ in accordance with the above-described GD-MS testing methodology.

TABLE 12

| Sample # | Isotope | Test #1 | Test #2 | Test #3 | Test #4 | Avg. |
|---|---|---|---|---|---|---|
| F-064 | ⁵⁶Fe | 40 | 55 | 48 | 46 | 47.25 |
| F-064 | ¹⁹⁴Pt | <0.64 | <1.8 | <2 | <2 | 1.61 |
| F-064 | ¹⁹⁵Pt | 0.47 | 1.9 | 0.87 | <0.4 | 0.91 |

### Example #13: Tailored Sample F-066

Table 13 below includes GD-MS data obtained for a tailored graphite rod sample ‘F-066’ in accordance with the above-described GD-MS testing methodology.

TABLE 13

| Sample # | Isotope | Test #1 | Test #2 | Test #3 | Test #4 | Avg. |
|---|---|---|---|---|---|---|
| F-066 | ⁵⁶Fe | 45 | 58 | 60 | 57 | 55 |
| F-066 | ¹⁹⁴Pt | <0.49 | <1.2 | <1.5 | <1.6 | 1.1975 |
| F-066 | ¹⁹⁵Pt | 0.9 | 0.84 | 1.6 | 0.71 | 1.0125 |

### Example #14: Tailored Sample F-068

Table 14 below includes GD-MS data obtained for a tailored graphite rod sample ‘F-068’ in accordance with the above-described GD-MS testing methodology.

TABLE 14

| Sample # | Isotope | Test #1 | Test #2 | Test #3 | Test #4 | Avg. |
|---|---|---|---|---|---|---|
| F-068 | ⁵⁶Fe | 20 | 54 | 57 | 56 | 46.75 |
| F-068 | ¹⁹⁴Pt | <0.16 | <0.66 | <0.91 | <1 | 0.6825 |
| F-068 | ¹⁹⁵Pt | 0.24 | 0.36 | 0.29 | 0.81 | 0.425 |

### Example #15: Tailored Sample F-069

Table 15 below includes GD-MS data obtained for a tailored graphite rod sample ‘F-069’ in accordance with the above-described GD-MS testing methodology.

TABLE 15

| Sample # | Isotope | Test #1 | Test #2 | Test #3 | Test #4 | Avg. |
|---|---|---|---|---|---|---|
| F-069 | ⁵⁶Fe | 47 | 60 | 58 | 50 | 53.75 |
| F-069 | ¹⁹⁴Pt | <0.56 | <1.6 | <1.9 | <1.9 | 1.49 |
| F-069 | ¹⁹⁵Pt | 0.25 | 0.73 | <0.36 | <0.38 | 0.43 |

### Example #16: Tailored Sample F-113

Table 16 below includes GD-MS data obtained for a tailored graphite rod sample ‘F-113’ in accordance with the above-described GD-MS testing methodology.

TABLE 16

| Sample # | Isotope | Test #1 | Test #2 | Test #3 | Test #4 | Avg. |
|---|---|---|---|---|---|---|
| F-113 | ⁵⁶Fe | 22 | 42 | 31 | 25 | 30 |
| F-113 | ¹⁹⁴Pt | <1.6 | <8.7 | <10 | <10 | 7.575 |
| F-113 | ¹⁹⁵Pt | <0.32 | <1.7 | <2 | <2 | 1.505 |

### Example #17: Tailored Sample F-114

Table 17 below includes GD-MS data obtained for a tailored graphite rod sample ‘F-114’ in accordance with the above-described GD-MS testing methodology.

TABLE 17

| Sample # | Isotope | Test #1 | Test #2 | Test #3 | Test #4 | Avg. |
|---|---|---|---|---|---|---|
| F-114 | ⁵⁶Fe | 18 | 18 | 12 | 11 | 14.75 |
| F-114 | ¹⁹⁴Pt | <0.75 | <1.7 | <2 | <2.1 | 1.6375 |
| F-114 | ¹⁹⁵Pt | <0.15 | <0.33 | <0.39 | <0.42 | 0.3225 |

### Example #18: Tailored Sample F-115

Table 18 below includes GD-MS data obtained for a tailored graphite rod sample ‘F-115’ in accordance with the above-described GD-MS testing methodology.

TABLE 18

| Sample # | Isotope | Test #1 | Test #2 | Test #3 | Test #4 | Avg. |
|---|---|---|---|---|---|---|
| F-115 | ⁵⁶Fe | 25 | 39 | 33 | 32 | 32.25 |
| F-115 | ¹⁹⁴Pt | <1.6 | <4.2 | <4.6 | <4.7 | 3.775 |
| F-115 | ¹⁹⁵Pt | <0.31 | <0.81 | <0.89 | <0.92 | 0.7325 |

### Example #19: Tailored Sample F-116

Table 19 below includes GD-MS data obtained for a tailored graphite rod sample ‘F-116’ in accordance with the above-described GD-MS testing methodology.

TABLE 19

| Sample # | Isotope | Test #1 | Test #2 | Test #3 | Test #4 | Avg. |
|---|---|---|---|---|---|---|
| F-116 | ⁵⁶Fe | 35 | 33 | 27 | 21 | 29 |
| F-116 | ¹⁹⁴Pt | <1.4 | <3.2 | <3.4 | <3.5 | 2.875 |
| F-116 | ¹⁹⁵Pt | <0.27 | <0.61 | <0.66 | <0.68 | 0.555 |

### Example #20: Tailored Sample F-117

Table 20 below includes GD-MS data obtained for a tailored graphite rod sample ‘F-117’ in accordance with the above-described GD-MS testing methodology.

TABLE 20

| Sample # | Isotope | Test #1 | Test #2 | Test #3 | Test #4 | Avg. |
|---|---|---|---|---|---|---|
| F-117 | ⁵⁶Fe | 4.7 | 12 | 13 | 15 | 11.175 |
| F-117 | ¹⁹⁴Pt | <0.39 | <2.4 | <3.3 | <3.8 | 2.4725 |
| F-117 | ¹⁹⁵Pt | 0.43 | 1.6 | <0.65 | <0.75 | 0.8575 |

### Example #21: Tailored Sample F-118

Table 21 below includes GD-MS data obtained for a tailored graphite rod sample ‘F-118’ in accordance with the above-described GD-MS testing methodology.

TABLE 21

| Sample # | Isotope | Test #1 | Test #2 | Test #3 | Test #4 | Avg. |
|---|---|---|---|---|---|---|
| F-118 | ⁵⁶Fe | 15 | 17 | 14 | 14 | 15 |
| F-118 | ¹⁹⁴Pt | <1.2 | <2.8 | <3.3 | <3.5 | 2.7 |
| F-118 | ¹⁹⁵Pt | 1.8 | 0.83 | 2.6 | 0.34 | 1.3925 |

### Example #22: Tailored Sample F-119

Table 22 below includes GD-MS data obtained for a tailored graphite rod sample ‘F-119’ in accordance with the above-described GD-MS testing methodology.

TABLE 22

| Sample # | Isotope | Test #1 | Test #2 | Test #3 | Test #4 | Avg. |
|---|---|---|---|---|---|---|
| F-119 | ⁵⁶Fe | 13 | 15 | 9.9 | 8.7 | 11.65 |
| F-119 | ¹⁹⁴Pt | <1.1 | <2.5 | <3 | <3.3 | 2.475 |
| F-119 | ¹⁹⁵Pt | 0.72 | 0.99 | <0.58 | <0.64 | 0.7325 |

### Example #23: Tailored Sample F-120

Table 23 below includes GD-MS data obtained for a tailored graphite rod sample ‘F-120’ in accordance with the above-described GD-MS testing methodology.

TABLE 23

| Sample # | Isotope | Test #1 | Test #2 | Test #3 | Test #4 | Avg. |
|---|---|---|---|---|---|---|
| F-120 | ⁵⁶Fe | 11 | 16 | 14 | 20 | 15.25 |
| F-120 | ¹⁹⁴Pt | <1.3 | <3.3 | <3.6 | <3.7 | 2.975 |
| F-120 | ¹⁹⁵Pt | 0.58 | 1.6 | <0.7 | <0.72 | 0.9 |

### Example #24: Tailored Sample F-144

Table 24 below includes GD-MS data obtained for a tailored graphite rod sample ‘F-144’ in accordance with the above-described GD-MS testing methodology.

TABLE 24

| Sample # | Isotope | Test #1 | Test #2 | Test #3 | Test #4 | Avg. |
|---|---|---|---|---|---|---|
| F-144 | ⁵⁶Fe | 2.4 | 6.4 | 10 | 9.2 | 7 |
| F-144 | ¹⁹⁴Pt | <0.29 | <2 | <2.8 | <3.1 | 2.0475 |
| F-144 | ¹⁹⁵Pt | 0.11 | 1.2 | 3.4 | 1.7 | 1.6025 |

### Example #25: Tailored Sample F-145

Table 25 below includes GD-MS data obtained for a tailored graphite rod sample ‘F-145’ in accordance with the above-described GD-MS testing methodology.

TABLE 25

| Sample # | Isotope | Test #1 | Test #2 | Test #3 | Test #4 | Avg. |
|---|---|---|---|---|---|---|
| F-145 | ⁵⁶Fe | 12 | 8.9 | 7.6 | 6.2 | 8.675 |
| F-145 | ¹⁹⁴Pt | <1.3 | <2.2 | <2.3 | <2.3 | 2.025 |
| F-145 | ¹⁹⁵Pt | 0.44 | 1.3 | 0.66 | 1.4 | 0.95 |

### Example #26: Tailored Sample F-146

Table 26 below includes GD-MS data obtained for a tailored graphite rod sample ‘F-146’ in accordance with the above-described GD-MS testing methodology.

TABLE 26

| Sample # | Isotope | Test #1 | Test #2 | Test #3 | Test #4 | Avg. |
|---|---|---|---|---|---|---|
| F-146 | ⁵⁶Fe | 3 | 3.7 | 2.6 | 2.2 | 2.875 |
| F-146 | ¹⁹⁴Pt | <1 | <2.4 | <2.6 | <2.6 | 2.15 |
| F-146 | ¹⁹⁵Pt | 0.4 | 0.69 | 0.25 | 0.89 | 0.5575 |

### Example #27: Tailored Sample F-147

Table 27 below includes GD-MS data obtained for a tailored graphite rod sample ‘F-147’ in accordance with the above-described GD-MS testing methodology.

TABLE 27

| Sample # | Isotope | Test #1 | Test #2 | Test #3 | Test #4 | Avg. |
|---|---|---|---|---|---|---|
| F-147 | ⁵⁶Fe | 13 | 12 | 9.8 | 7.8 | 10.65 |
| F-147 | ¹⁹⁴Pt | <1.2 | <2.4 | <2.5 | <2.5 | 2.15 |
| F-147 | ¹⁹⁵Pt | 0.52 | <0.47 | 0.84 | 0.96 | 0.6975 |

### Example #28: Tailored Sample F-148

Table 28 below includes GD-MS data obtained for a tailored graphite rod sample ‘F-148’ in accordance with the above-described GD-MS testing methodology.

TABLE 28

| Sample # | Isotope | Test #1 | Test #2 | Test #3 | Test #4 | Avg. |
|---|---|---|---|---|---|---|
| F-148 | ⁵⁶Fe | 12 | 9.4 | 9.7 | 6.1 | 9.3 |
| F-148 | ¹⁹⁴Pt | <1.4 | <2.7 | <3 | <3.1 | 2.55 |
| F-148 | ¹⁹⁵Pt | 1.7 | <0.54 | <0.59 | <0.61 | 0.86 |

### Example #29: Tailored Sample F-149

Table 29 below includes GD-MS data obtained for a tailored graphite rod sample ‘F-149’ in accordance with the above-described GD-MS testing methodology.

TABLE 29

| Sample # | Isotope | Test #1 | Test #2 | Test #3 | Test #4 | Avg. |
|---|---|---|---|---|---|---|
| F-149 | ⁵⁶Fe | 16 | 13 | 10 | 8.8 | 11.95 |
| F-149 | ¹⁹⁴Pt | <1.3 | <2.4 | <2.4 | <2.5 | 2.15 |
| F-149 | ¹⁹⁵Pt | 0.69 | <0.47 | <0.48 | <0.48 | 0.53 |

### Example #30: Tailored Sample F-150

Table 30 below includes GD-MS data obtained for a tailored graphite rod sample ‘F-150’ in accordance with the above-described GD-MS testing methodology.

TABLE 30

| Sample # | Isotope | Test #1 | Test #2 | Test #3 | Test #4 | Avg. |
|---|---|---|---|---|---|---|
| F-150 | ⁵⁶Fe | 12 | 13 | 12 | 4.7 | 10.425 |
| F-150 | ¹⁹⁴Pt | <31 | <37 | <38 | <37 | 35.75 |
| F-150 | ¹⁹⁵Pt | <6 | <7.3 | <7.4 | <7.2 | 6.975 |

### Example #31: Tailored Sample F-152

Table 31 below includes GD-MS data obtained for a tailored graphite rod sample ‘F-152’ in accordance with the above-described GD-MS testing methodology.

TABLE 31

| Sample # | Isotope | Test #1 | Test #2 | Test #3 | Test #4 | Avg. |
|---|---|---|---|---|---|---|
| F-152 | ⁵⁶Fe | 10 | 10 | 10 | 9.2 | 9.8 |
| F-152 | ¹⁹⁴Pt | <0.7 | <1.3 | <1.5 | <1.5 | 1.25 |
| F-152 | ¹⁹⁵Pt | 0.61 | 1.1 | 1.3 | 0.8 | 0.9525 |

### Example #32: Tailored Sample F-153

Table 32 below includes GD-MS data obtained for a tailored graphite rod sample ‘F-153’ in accordance with the above-described GD-MS testing methodology.

TABLE 32

| Sample # | Isotope | Test #1 | Test #2 | Test #3 | Test #4 | Avg. |
|---|---|---|---|---|---|---|
| F-153 | ⁵⁶Fe | 10 | 7.1 | 6.6 | 5.9 | 7.4 |
| F-153 | ¹⁹⁴Pt | <1.4 | <1.7 | <1.7 | <1.7 | 1.625 |
| F-153 | ¹⁹⁵Pt | 0.33 | 0.67 | 0.91 | 0.68 | 0.6475 |

### Example #33: Tailored Sample F-154

Table 33 below includes GD-MS data obtained for a tailored graphite rod sample ‘F-154’ in accordance with the above-described GD-MS testing methodology.

TABLE 33

| Sample # | Isotope | Test #1 | Test #2 | Test #3 | Test #4 | Avg. |
|---|---|---|---|---|---|---|
| F-154 | ⁵⁶Fe | 6.6 | 4.1 | 3.6 | 3.6 | 4.475 |
| F-154 | ¹⁹⁴Pt | <0.8 | <1.3 | <1.8 | <1.7 | 1.4 |
| F-154 | ¹⁹⁵Pt | 0.73 | 1.2 | 0.95 | 1.1 | 0.995 |

### Example #34: Tailored Sample F-228

Table 34 below includes GD-MS data obtained for a tailored graphite rod sample ‘F-228’ in accordance with the above-described GD-MS testing methodology.

TABLE 34

| Sample # | Isotope | Test #1 | Test #2 | Test #3 | Test #4 | Avg. |
|---|---|---|---|---|---|---|
| F-228 | ⁵⁶Fe | 5 | 10 | 7 | 5.1 | 6.775 |
| F-228 | ¹⁹⁴Pt | <0.87 | <2.6 | <2.9 | <2.9 | 2.3175 |
| F-228 | ¹⁹⁵Pt | 0.72 | 1.7 | 1.4 | 1.7 | 1.38 |

### Example #35: Tailored Sample F-229

Table 35 below includes GD-MS data obtained for a tailored graphite rod sample ‘F-229’ in accordance with the above-described GD-MS testing methodology.

TABLE 35

| Sample # | Isotope | Test #1 | Test #2 | Test #3 | Test #4 | Avg. |
|---|---|---|---|---|---|---|
| F-229 | ⁵⁶Fe | 2.3 | 3.3 | 3.4 | 3.7 | 3.175 |
| F-229 | ¹⁹⁴Pt | <0.91 | <2 | <2.1 | <2.1 | 1.7775 |
| F-229 | ¹⁹⁵Pt | 1.2 | 0.68 | 0.83 | 1.6 | 1.0775 |

### Example #36: Tailored Sample F-171

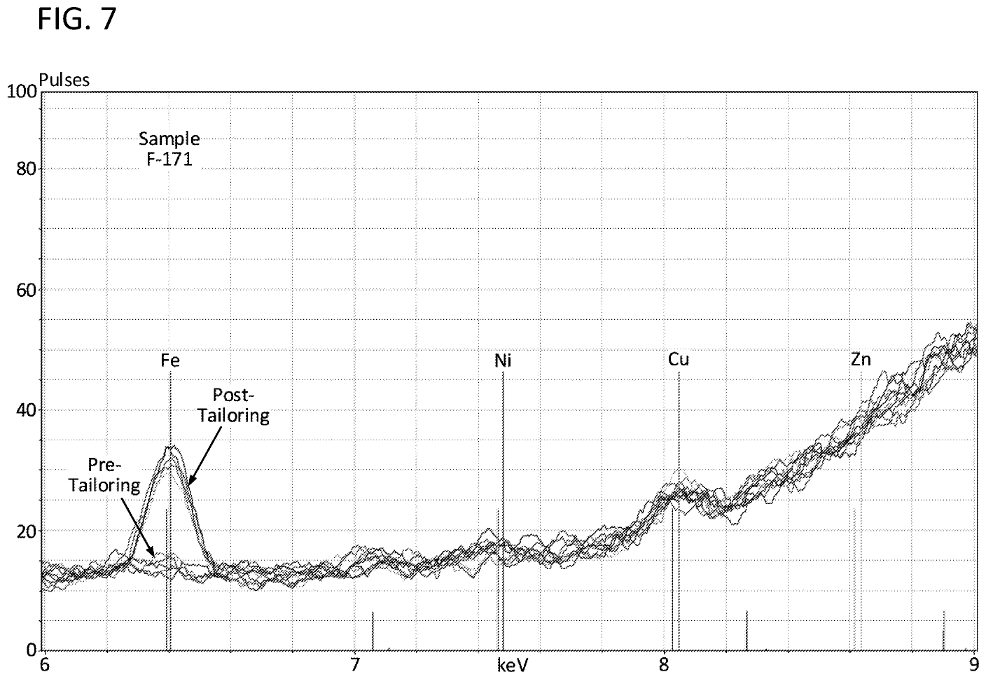

FIG. 7 graphically illustrates spectra obtained from ED-XRF of a graphite rod sample (sample label ‘F-171’) both before and after tailoring in accordance with an embodiment of the present disclosure.

Discussion of Results

As demonstrated by the various examples provided above, ED-XRF analysis shows formation of iron (Fe) and/or platinum (Pt) in a given tailored carbon (C) graphite rod, and GD-MS analysis confirms and quantifies the amount(s) generated in each example case. As can be seen from FIGS. 4-7, for instance, the post-tailoring spectra demonstrate a clearly greater presence of iron (Fe) (e.g., 50-801 ppm) based on K_{α} X-ray line analysis, whereas no discernible peak is evident from the pre-tailoring spectra. In at least some instances, there was observed a change in the presence of iron (Fe) in the range of two orders of magnitude. Moreover, scanning electron microscope (SEM) analysis of several of the tested carbon (C) graphite rods showed definite pockets of iron (Fe) material. More specifically, the observed production patterns generally resembled ore patterns and were not indicative of merely a deposition pattern. In each example case, the graphite sample had not been in contact with any such observed metal before, during, or after being subjected to tailoring techniques disclosed herein.

Table 36 below includes GD-MS data on ⁵⁶Fe obtained for one untailored graphite rod (F-002) and 34 tailored graphite rods (F-003 through F-229) in accordance with the above-described GD-MS testing methodology, using techniques disclosed herein, in accordance with some embodiments of the present disclosure.

TABLE 36

| Sample # | Isotope | Test #1 | Test #2 | Test #3 | Test #4 | Avg. |
|---|---|---|---|---|---|---|
| F-002 | ⁵⁶Fe | 1.8 | 4 | 4.7 | 6.1 | 4.15 |
| (Control) | | | | | | |
| F-003 | ⁵⁶Fe | 220 | 440 | 280 | 210 | 287.5 |
| F-004 | ⁵⁶Fe | 340 | 530 | 470 | 400 | 435 |
| F-005 | ⁵⁶Fe | 300 | 270 | 230 | 210 | 252.5 |
| F-006 | ⁵⁶Fe | 180 | 300 | 270 | 240 | 247.5 |
| F-008 | ⁵⁶Fe | 910 | 680 | 500 | 390 | 620 |
| F-016 | ⁵⁶Fe | 490 | 670 | 580 | 560 | 575 |
| F-026 | ⁵⁶Fe | 640 | 660 | 560 | 490 | 587.5 |
| F-027 | ⁵⁶Fe | 350 | 530 | 510 | 460 | 462.5 |
| F-028 | ⁵⁶Fe | 510 | 590 | 540 | 490 | 532.5 |
| F-029 | ⁵⁶Fe | 370 | 490 | 420 | 350 | 407.5 |
| F-064 | ⁵⁶Fe | 40 | 55 | 48 | 46 | 47.25 |
| F-066 | ⁵⁶Fe | 45 | 58 | 60 | 57 | 55 |
| F-068 | ⁵⁶Fe | 20 | 54 | 57 | 56 | 46.75 |
| F-069 | ⁵⁶Fe | 47 | 60 | 58 | 50 | 53.75 |
| F-113 | ⁵⁶Fe | 22 | 42 | 31 | 25 | 30 |
| F-114 | ⁵⁶Fe | 18 | 18 | 12 | 11 | 14.75 |
| F-115 | ⁵⁶Fe | 25 | 39 | 33 | 32 | 32.25 |
| F-116 | ⁵⁶Fe | 35 | 33 | 27 | 21 | 29 |
| F-117 | ⁵⁶Fe | 4.7 | 12 | 13 | 15 | 11.175 |
| F-118 | ⁵⁶Fe | 15 | 17 | 14 | 14 | 15 |
| F-119 | ⁵⁶Fe | 13 | 15 | 9.9 | 8.7 | 11.65 |
| F-120 | ⁵⁶Fe | 11 | 16 | 14 | 20 | 15.25 |
| F-144 | ⁵⁶Fe | 2.4 | 6.4 | 10 | 9.2 | 7 |
| F-145 | ⁵⁶Fe | 12 | 8.9 | 7.6 | 6.2 | 8.675 |
| F-146 | ⁵⁶Fe | 3 | 3.7 | 2.6 | 2.2 | 2.875 |
| F-147 | ⁵⁶Fe | 13 | 12 | 9.8 | 7.8 | 10.65 |
| F-148 | ⁵⁶Fe | 12 | 9.4 | 9.7 | 6.1 | 9.3 |
| F-149 | ⁵⁶Fe | 16 | 13 | 10 | 8.8 | 11.95 |
| F-150 | ⁵⁶Fe | 12 | 13 | 12 | 4.7 | 10.425 |
| F-152 | ⁵⁶Fe | 10 | 10 | 10 | 9.2 | 9.8 |
| F-153 | ⁵⁶Fe | 10 | 7.1 | 6.6 | 5.9 | 7.4 |
| F-154 | ⁵⁶Fe | 6.6 | 4.1 | 3.6 | 3.6 | 4.475 |
| F-228 | ⁵⁶Fe | 5 | 10 | 7 | 5.1 | 6.775 |
| F-229 | ⁵⁶Fe | 2.3 | 3.3 | 3.4 | 3.7 | 3.175 |

Similar observations were found regarding a clearly greater presence of platinum (Pt) (e.g., for sample ‘F-150,’ up to twenty-six times greater than the control) based on GD-MS analysis. As previously noted, in each example case, the graphite sample had not been in contact with any such observed metal before, during, or after being subjected to tailoring techniques disclosed herein.

Table 37 below includes GD-MS data on ¹⁹⁴Pt obtained for one untailored graphite rod (F-002) and 34 tailored graphite rods (F-003 through F-229) in accordance with the above-described GD-MS testing methodology, using techniques disclosed herein, in accordance with some embodiments of the present disclosure. Table 38 below includes GD-MS data on ¹⁹⁵Pt obtained for one untailored graphite rod (F-002) and 34 tailored graphite rods (F-003 through F-229) in accordance with the above-described GD-MS testing methodology, using techniques disclosed herein, in accordance with some embodiments of the present disclosure.

TABLE 37

| Sample # | Isotope | Test #1 | Test #2 | Test #3 | Test #4 | Avg. |
|---|---|---|---|---|---|---|
| F-002 | ¹⁹⁴Pt | <0.36 | <1.4 | <1.7 | <1.9 | 1.34 |
| (Control) | | | | | | |
| F-003 | ¹⁹⁴Pt | <0.68 | <1.7 | <1.9 | <2 | 1.57 |
| F-004 | ¹⁹⁴Pt | <0.54 | <1.8 | <2 | <2 | 1.585 |
| F-005 | ¹⁹⁴Pt | <0.32 | <0.82 | <1.1 | <1.2 | 0.86 |
| F-006 | ¹⁹⁴Pt | <0.15 | <0.86 | <1.1 | <1.2 | 0.8275 |
| F-008 | ¹⁹⁴Pt | <0.37 | <0.91 | <1.1 | <1.2 | 0.895 |
| F-016 | ¹⁹⁴Pt | <0.66 | <1.9 | <2 | <2.2 | 1.69 |
| F-026 | ¹⁹⁴Pt | <0.43 | <1.1 | <1.3 | <1.3 | 1.0325 |
| F-027 | ¹⁹⁴Pt | <0.23 | <0.85 | <1.1 | <1.2 | 0.845 |
| F-028 | ¹⁹⁴Pt | <0.43 | <1.1 | <1.3 | <1.4 | 1.0575 |
| F-029 | ¹⁹⁴Pt | <0.35 | <0.92 | <1.1 | <1.1 | 0.8675 |
| F-064 | ¹⁹⁴Pt | <0.64 | <1.8 | <2 | <2 | 1.61 |
| F-066 | ¹⁹⁴Pt | <0.49 | <1.2 | <1.5 | <1.6 | 1.1975 |
| F-068 | ¹⁹⁴Pt | <0.16 | <0.66 | <0.91 | <1 | 0.6825 |
| F-069 | ¹⁹⁴Pt | <0.56 | <1.6 | <1.9 | <1.9 | 1.49 |
| F-113 | ¹⁹⁴Pt | <1.6 | <8.7 | <10 | <10 | 7.575 |
| F-114 | ¹⁹⁴Pt | <0.75 | <1.7 | <2 | <2.1 | 1.6375 |
| F-115 | ¹⁹⁴Pt | <1.6 | <4.2 | <4.6 | <4.7 | 3.775 |
| F-116 | ¹⁹⁴Pt | <1.4 | <3.2 | <3.4 | <3.5 | 2.875 |
| F-117 | ¹⁹⁴Pt | <0.39 | <2.4 | <3.3 | <3.8 | 2.4725 |
| F-118 | ¹⁹⁴Pt | <1.2 | <2.8 | <3.3 | <3.5 | 2.7 |
| F-119 | ¹⁹⁴Pt | <1.1 | <2.5 | <3 | <3.3 | 2.475 |
| F-120 | ¹⁹⁴Pt | <1.3 | <3.3 | <3.6 | <3.7 | 2.975 |
| F-144 | ¹⁹⁴Pt | <0.29 | <2 | <2.8 | <3.1 | 2.0475 |
| F-145 | ¹⁹⁴Pt | <1.3 | <2.2 | <2.3 | <2.3 | 2.025 |
| F-146 | ¹⁹⁴Pt | <1 | <2.4 | <2.6 | <2.6 | 2.15 |
| F-147 | ¹⁹⁴Pt | <1.2 | <2.4 | <2.5 | <2.5 | 2.15 |
| F-148 | ¹⁹⁴Pt | <1.4 | <2.7 | <3 | <3.1 | 2.55 |
| F-149 | ¹⁹⁴Pt | <1.3 | <2.4 | <2.4 | <2.5 | 2.15 |
| F-150 | ¹⁹⁴Pt | <31 | <37 | <38 | <37 | 35.75 |
| F-152 | ¹⁹⁴Pt | <0.7 | <1.3 | <1.5 | <1.5 | 1.25 |
| F-153 | ¹⁹⁴Pt | <1.4 | <1.7 | <1.7 | <1.7 | 1.625 |
| F-154 | ¹⁹⁴Pt | <0.8 | <1.3 | <1.8 | <1.7 | 1.4 |
| F-228 | ¹⁹⁴Pt | <0.87 | <2.6 | <2.9 | <2.9 | 2.3175 |
| F-229 | ¹⁹⁴Pt | <0.91 | <2 | <2.1 | <2.1 | 1.7775 |

TABLE 38

| Sample # | Isotope | Test #1 | Test #2 | Test #3 | Test #4 | Avg. |
|---|---|---|---|---|---|---|
| F-002 | ¹⁹⁵Pt | 0.17 | 0.63 | 0.4 | 0.54 | 0.435 |
| (Control) | | | | | | |
| F-003 | ¹⁹⁵Pt | 0.41 | 0.92 | <0.72 | <0.78 | 0.7075 |
| F-004 | ¹⁹⁵Pt | <0.1 | <0.35 | <0.38 | <0.38 | 0.3025 |
| F-005 | ¹⁹⁵Pt | 0.19 | 0.59 | 1.1 | 0.6 | 0.62 |
| F-006 | ¹⁹⁵Pt | <0.047 | <0.27 | <0.34 | <0.36 | 0.25425 |
| F-008 | ¹⁹⁵Pt | 0.48 | 0.84 | 1 | 0.74 | 0.765 |
| F-016 | ¹⁹⁵Pt | 0.45 | 1.5 | 1.6 | 1.1 | 1.1625 |
| F-026 | ¹⁹⁵Pt | <0.084 | <0.21 | <0.25 | <0.26 | 0.201 |
| F-027 | ¹⁹⁵Pt | 0.8 | 0.49 | 0.79 | 0.98 | 0.765 |
| F-028 | ¹⁹⁵Pt | 0.47 | 1 | 1.2 | 0.61 | 0.82 |
| F-029 | ¹⁹⁵Pt | 0.36 | 0.58 | <0.21 | <0.22 | 0.3425 |
| F-064 | ¹⁹⁵Pt | 0.47 | 1.9 | 0.87 | <0.4 | 0.91 |
| F-066 | ¹⁹⁵Pt | 0.9 | 0.84 | 1.6 | 0.71 | 1.0125 |
| F-068 | ¹⁹⁵Pt | 0.24 | 0.36 | 0.29 | 0.81 | 0.425 |
| F-069 | ¹⁹⁵Pt | 0.25 | 0.73 | <0.36 | <0.38 | 0.43 |
| F-113 | ¹⁹⁵Pt | <0.32 | <1.7 | <2 | <2 | 1.505 |
| F-114 | ¹⁹⁵Pt | <0.15 | <0.33 | <0.39 | <0.42 | 0.3225 |
| F-115 | ¹⁹⁵Pt | <0.31 | <0.81 | <0.89 | <0.92 | 0.7325 |
| F-116 | ¹⁹⁵Pt | <0.27 | <0.61 | <0.66 | <0.68 | 0.555 |
| F-117 | ¹⁹⁵Pt | 0.43 | 1.6 | <0.65 | <0.75 | 0.8575 |
| F-118 | ¹⁹⁵Pt | 1.8 | 0.83 | 2.6 | 0.34 | 1.3925 |
| F-119 | ¹⁹⁵Pt | 0.72 | 0.99 | <0.58 | <0.64 | 0.7325 |
| F-120 | ¹⁹⁵Pt | 0.58 | 1.6 | <0.7 | <0.72 | 0.9 |
| F-144 | ¹⁹⁵Pt | 0.11 | 1.2 | 3.4 | 1.7 | 1.6025 |
| F-145 | ¹⁹⁵Pt | 0.44 | 1.3 | 0.66 | 1.4 | 0.95 |
| F-146 | ¹⁹⁵Pt | 0.4 | 0.69 | 0.25 | 0.89 | 0.5575 |
| F-147 | ¹⁹⁵Pt | 0.52 | <0.47 | 0.84 | 0.96 | 0.6975 |
| F-148 | ¹⁹⁵Pt | 1.7 | <0.54 | <0.59 | <0.61 | 0.86 |
| F-149 | ¹⁹⁵Pt | 0.69 | <0.47 | <0.48 | <0.48 | 0.53 |
| F-150 | ¹⁹⁵Pt | <6 | <7.3 | <7.4 | <7.2 | 6.975 |
| F-152 | ¹⁹⁵Pt | 0.61 | 1.1 | 1.3 | 0.8 | 0.9525 |
| F-153 | ¹⁹⁵Pt | 0.33 | 0.67 | 0.91 | 0.68 | 0.6475 |
| F-154 | ¹⁹⁵Pt | 0.73 | 1.2 | 0.95 | 1.1 | 0.995 |
| F-228 | ¹⁹⁵Pt | 0.72 | 1.7 | 1.4 | 1.7 | 1.38 |
| F-229 | ¹⁹⁵Pt | 1.2 | 0.68 | 0.83 | 1.6 | 1.0775 |

In total, the analytical depth of these results and the employed GD-MS protocol clearly suggest that both bulk production and surficial generation of iron (Fe) and/or platinum (Pt) are possible utilizing techniques described herein, in accordance with some embodiments. As described herein, the disclosed techniques may be utilized, more generally, in producing any of a wide range of metals (and/or alloys thereof), in accordance with some embodiments.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description. Future-filed applications claiming priority to this application may claim the disclosed subject matter in a different manner and generally may include any set of one or more limitations as variously disclosed or otherwise demonstrated herein.

1. A method of manufacturing a metal or alloy thereof, the method comprising:
delivering at least one gas to interact with a carbon sample, wherein the at least one gas is non-reactive with respect to the carbon sample; and
subjecting the carbon sample to at least one of electromagnetic radiation, an electromagnetic field, and subatomic particle bombardment such that the carbon sample thereafter further comprises the metal or alloy thereof without the carbon sample previously having been in contact with said metal or alloy thereof, wherein:
the electromagnetic radiation is selected from the group consisting of light, laser light, an electromagnetic field, and gamma radiation; and
the subatomic particle bombardment involves subatomic particles selected from the group consisting of protons, neutrons, and electrons.

2. The method of claim 1, wherein prior to carrying out the method, the carbon sample comprises at least 95% graphite by weight.

3. The method of claim 1, wherein the metal or alloy thereof comprises a rare earth metal.

4. The method of claim 1, wherein the metal or alloy thereof comprises a platinum-group element.

5. The method of claim 4, wherein the metal or alloy thereof comprises platinum.

6. The method of claim 5, wherein the amount of platinum present is at least one order of magnitude higher than prior to carrying out the method.

7. The method of claim 1, wherein the metal or alloy thereof comprises iron.

8. The method of claim 7, wherein the amount of iron present is at least one order of magnitude higher than prior to carrying out the method.

9. The method of claim 7, wherein the amount of iron present is at least two orders of magnitude higher than prior to carrying out the method.

10. The method of claim 1, wherein the metal or alloy thereof comprises a transition metal.

11. The method of claim 1, wherein subjecting the carbon sample to at least one of electromagnetic radiation, an electromagnetic field, and subatomic particle bombardment occurs either:
before delivering the at least one gas to interact with the carbon sample;
during delivering the at least one gas to interact with the carbon sample; or
after delivering the at least one gas to interact with the carbon sample.

12. The method of claim 1, wherein subjecting the carbon sample to at least one of electromagnetic radiation, an electromagnetic field, and subatomic particle bombardment occurs at least two of:
before delivering the at least one gas to interact with the carbon sample;
during delivering the at least one gas to interact with the carbon sample; and
after delivering the at least one gas to interact with the carbon sample.

13. The method of claim 1, wherein subjecting the carbon sample to at least one of electromagnetic radiation, an electromagnetic field, and subatomic particle bombardment occurs each of:
before delivering the at least one gas to interact with the carbon sample;
during delivering the at least one gas to interact with the carbon sample; and
after delivering the at least one gas to interact with the carbon sample.

14. The method of claim 1, further comprising:
subjecting the carbon sample to induction heating.

15. The method of claim 14, wherein subjecting the carbon sample to the induction heating occurs either:
before delivering the at least one gas to interact with the carbon sample;
during delivering the at least one gas to interact with the carbon sample; or
after delivering the at least one gas to interact with the carbon sample.

16. The method of claim 14, wherein subjecting the carbon sample to the induction heating occurs at least two of:
before delivering the at least one gas to interact with the carbon sample;
during delivering the at least one gas to interact with the carbon sample; and
after delivering the at least one gas to interact with the carbon sample.

17. The method of claim 14, wherein subjecting the carbon sample to the induction heating occurs at each of:
before delivering the at least one gas to interact with the carbon sample;
during delivering the at least one gas to interact with the carbon sample; and
after delivering the at least one gas to interact with the carbon sample.

18. The method of claim 1, wherein prior to delivering the at least one gas to interact with the carbon sample, the method further comprises:
subjecting the at least one gas to at least one of:
(a) at least one of electromagnetic radiation and subatomic particle bombardment; and
(b) at least one of an electromagnetic field and induction heating.

19. A metal or alloy thereof manufactured via the method of claim 1.

20. A composition comprising:
a carbon body; and
a manufactured metal or alloy thereof hosted by the carbon body, wherein the manufactured metal or alloy is of an ore-type formation pattern as hosted by the carbon body.

21. The composition of claim 20, wherein the carbon body comprises at least 95% graphite by weight.

22. The composition of claim 20, wherein the metal or alloy thereof comprises a rare earth metal.

23. The composition of claim 20, wherein the metal or alloy thereof comprises a platinum-group element.

24. The composition of claim 23, wherein the metal or alloy thereof comprises platinum.

25. The composition of claim 20, wherein the metal or alloy thereof comprises iron.

26. The composition of claim 20, wherein the metal or alloy thereof comprises a transition metal.

27. A system configured to manufacture a metal or alloy thereof, the system comprising:
at least one sample containment configured to contain a carbon sample and to deliver at least one gas to interact with the carbon sample, wherein the at least one gas is non-reactive with respect to the carbon sample; and
at least one sample treatment source external to the at least one sample containment and configured to subject the carbon sample to at least one of electromagnetic radiation, an electromagnetic field, and subatomic particle bombardment such that the carbon sample thereafter further comprises the metal or alloy thereof without the carbon sample previously having been in contact with said metal or alloy thereof, wherein:
the electromagnetic radiation is selected from the group consisting of light, laser light, an electromagnetic field, and gamma radiation; and
the subatomic particle bombardment involves subatomic particles selected from the group consisting of protons, neutrons, and electrons.

28. The system of claim 27, further comprising a coil at least partially surrounding the at least one sample containment, wherein the coil is configured to be driven so as to subject the carbon sample to induction heating.

29. The system of claim 27, further comprising:
at least one gas containment configured to have the at least one gas flow therethrough to be delivered to interact with the carbon sample; and
at least one gas treatment source external to the at least one gas containment and configured to subject the at least one gas to at least one of:
(a) at least one of electromagnetic radiation and subatomic particle bombardment, wherein the electromagnetic radiation is selected from the group consisting of light, a static magnetic field, an alternating magnetic field, a static electric field, and an alternating electric field; and
(b) at least one of an electromagnetic field and induction heating.
